(19) United States
(12) Patent Application Publication
(10) Pub. No.: US 2026/0093775 A1
(43) Pub. Date: Apr. 2, 2026

(54) OSCILLATORY VECTOR MATRIX MULTIPLICATION FOR ANALOG IN-MEMORY COMPUTE (AIMC)

(71) Applicant: International Business Machines Corporation, Armonk, NY (US)

(72) Inventors: Charles Mackin, San Jose, CA (US); Jose Luquin, San Jose, CA (US)

(21) Appl. No.: 18/901,565

(22) Filed: Sep. 30, 2024

(51) Int. Cl. G06F 17/16; H03K 19/0185

(52) U.S. Cl. CPC G06F 17/16; H03K 19/018571

(57) ABSTRACT

An oscillatory matrix-vector multiplication device includes one or more oscillatory matrix-vector multiplication circuits. Each oscillatory matrix-vector multiplication circuit includes a first tunable resistive circuit that comprises a first complementary metal-oxide semiconductor (CMOS) transistor, a first activation input, and a first tunable resistive circuit output, wherein the first complementary metal-oxide semiconductor (CMOS) transistor includes a first gate input, a first input coupled to the first activation input and a first output coupled to the first tunable resistive circuit output, and wherein the first activation input is configured to receive an activation signal; and a programmable oscillator circuit coupled to the first gate input of the first tunable resistive circuit and configured to produce a control signal based on a given conductance.

### BACKGROUND

The present invention relates generally to the electrical, electronic and computer arts and, more particularly, to analog in-memory compute devices, machine learning, and machine learning circuitry.

Analog in-memory compute (AIMC) is an important component of machine learning and is usually performed by integrating charge, measuring an instantaneous current, and the like. For example, matrix vector multiplication (MVM) may be performed using analog in-memory compute. Activations are typically provided as input to the analog in-memory compute and are often encoded using pulse-width modulation.

### BRIEF SUMMARY

Principles of the invention provide systems and techniques for oscillatory vector matrix multiplication for analog in-memory compute.

In one aspect, an oscillatory matrix-vector multiplication device comprises one or more oscillatory matrix-vector multiplication circuits, each oscillatory matrix-vector multiplication circuit comprising a first tunable resistive circuit comprising a first complementary metal-oxide semiconductor (CMOS) transistor, a first activation input, and a first tunable resistive circuit output, wherein the first complementary metal-oxide semiconductor (CMOS) transistor comprises a first gate input, a first input coupled to the first activation input and a first output coupled to the first tunable resistive circuit output, and wherein the first activation input is configured to receive an activation signal; and a programmable oscillator circuit coupled to the first gate input of the first tunable resistive circuit and configured to produce a control signal based on a given conductance.

In one aspect, a method for controlling an oscillatory matrix-vector multiplication device comprises mapping a given weight to a duty cycle of a programmable oscillator circuit; configuring the programmable oscillator circuit to produce an oscillating signal with the mapped duty cycle; and applying the oscillating signal to a tunable resistive circuit.

In one aspect, an oscillatory matrix-vector multiplication device comprises an array of a plurality of oscillatory matrix-vector multiplication circuits, the array configured as a plurality of columns and a plurality of rows of the oscillatory matrix-vector multiplication circuits, each oscillatory matrix-vector multiplication circuit comprising a first tunable resistive circuit comprising a first complementary metal-oxide semiconductor (CMOS) transistor, a first activation input, and a first tunable resistive circuit output, wherein the first complementary metal-oxide semiconductor (CMOS) transistor comprises a first gate input, a first input coupled to the first activation input and a first output coupled to the first tunable resistive circuit output; a second tunable resistive circuit comprising a second complementary metal-oxide semiconductor (CMOS) transistor, a second activation input, and a second tunable resistive circuit output, wherein the second complementary metal-oxide semiconductor (CMOS) transistor comprises a second gate input, a second input coupled to the second activation input and a second output coupled to the second tunable resistive circuit output; a programmable oscillator circuit coupled to the first gate input of the first tunable resistive circuit and coupled to the second gate input of the second tunable resistive circuit and wherein the programmable oscillator circuit is configured to produce a control signal based on a given conductance; and a plurality of summation circuits, wherein the first input of each first tunable resistive circuit in a given row of the array and the second input of each second tunable resistive circuit in the given row of the array are coupled to an activation signal corresponding to the row, wherein the first tunable resistive circuit output of each first tunable resistive circuit in a given column of the array are coupled together and the second tunable resistive circuit output of each second tunable resistive circuit in the given column of the array are coupled together and wherein one of the plurality of summation circuits is configured to subtract a current on the coupled second tunable resistive circuit outputs of the second tunable resistive circuits in the given column of the array from the coupled first tunable resistive circuit outputs of the first tunable resistive circuits in the given column of the array.

In one aspect, a hardware description language (HDL) design structure encoded on a machine-readable data storage medium, the HDL design structure comprising elements that when processed in a computer-aided design system generates a machine-executable representation of a semiconductor structure, wherein the HDL design structure comprises an oscillatory matrix-vector multiplication device comprises one or more oscillatory matrix-vector multiplication circuits, each oscillatory matrix-vector multiplication circuit comprising a first tunable resistive circuit comprising a first complementary metal-oxide semiconductor (CMOS) transistor, a first activation input, and a first tunable resistive circuit output, wherein the first complementary metal-oxide semiconductor (CMOS) transistor comprises a first gate input, a first input coupled to the first activation input and a first output coupled to the first tunable resistive circuit output, and wherein the first activation input is configured to receive an activation signal; and a programmable oscillator circuit coupled to the first gate input of the first tunable resistive circuit and configured to produce a control signal based on a given conductance.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment or instructions executing on a remote processor, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects, as will be discussed further below. Features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1A illustrates a conventional architecture for performing a multiply and accumulate operation;

FIG. 1B illustrates a conventional circuit diagram for performing a multiply and accumulate operation;

FIG. 1C illustrates a conventional unit cell circuit diagram of an analog in-memory compute device for performing a multiply and accumulate operation;

FIG. 1D shows graphs of the probability distribution functions of weights, activations and multiply-accumulate results drawn independently from each other, in accordance with example embodiments;

FIG. 1E is a graph of column integrated charge vs. multiply-accumulate results for a conventional AIMC circuit of FIG. 1B, in accordance with example embodiments;

FIG. 2A illustrates an array of conductances for a conventional AIMC MVM implementation;

FIG. 2B illustrates a first embodiment of an oscillatory AIMC for MVM, in accordance with example embodiments;

FIG. 3 illustrates a second embodiment of an oscillatory AIMC for MVM, in accordance with example embodiments;

FIG. 4A illustrates a third embodiment of an oscillatory AIMC for MVM, in accordance with example embodiments;

FIG. 4B illustrates a circuit diagram for the example oscillatory AIMC of FIG. 4A integrated with the oscillator circuit, in accordance with example embodiments;

FIG. 4C illustrates a fourth embodiment of an oscillatory AIMC for MVM, in accordance with example embodiments;

FIG. 4D illustrates a fifth embodiment of an oscillatory AIMC for MVM, in accordance with example embodiments;

FIG. 4E illustrates a sixth embodiment of an oscillatory AIMC for MVM, in accordance with example embodiments;

FIG. 4F illustrates an example system for performing inferencing using an array of oscillatory AIMCs for MVM, in accordance with example embodiments;

FIG. 5A illustrates a graph of the gate voltage V_{GS} for the transistor 404 while the tunable resistor charges the capacitor, in accordance with example embodiments;

FIG. 5B illustrates graphs of nonlinear G and nonlinear Q, in accordance with example embodiments;

FIG. 6 illustrates six different duty cycles for five cycles, in accordance with example embodiments;

FIG. 7 illustrates the current, Ids, through the transistor for six different duty cycles for 5 cycles, in accordance with example embodiments;

FIG. 8 is a graph of column integrated charge vs. ideal multiply-accumulate results, in accordance with example embodiments;

FIG. 9 illustrates a variation of the circuit of FIG. 4B configured to simulate the voltage-dependence of using a phase change memory (PCM) device with some degree of voltage-dependent conductance, in accordance with example embodiments;

FIG. 10 is an example graph of integrated charge vs. programmed conductance, in accordance with example embodiments;

FIG. 11 is a graph of column integrated charge vs. ideal multiply-accumulate results for the circuit of FIG. 9, in accordance with example embodiments;

FIG. 12 is a graph that illustrates a mapping of weights to conductances, in accordance with example embodiments;

FIG. 13 depicts a computing environment according to an embodiment of the present invention; and

FIG. 14 is a flow diagram of a design process used in semiconductor design, manufacture, and/or test.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

Given the discussion herein (reference characters refer to the drawings discussed below), it will be appreciated that in one aspect, an exemplary method for controlling an oscillatory matrix-vector multiplication device, according to an aspect of the invention, includes the operations of mapping a given weight to a duty cycle of a programmable oscillator circuit 420; configuring the programmable oscillator circuit 420 to produce an oscillating signal with the mapped duty cycle; and applying the oscillating signal to a tunable resistive circuit. The technical benefits include oscillatory AIMC circuits for matrix-vector multiplication (MVM) using transmission gates, switched capacitor circuitry and the like where an oscillator is applied to the gate(s) of the transistors of the MVM circuitry to implement a given conductance; usage of high input impedance gates for incorporating the oscillatory circuit into the AIMC circuit to provide independence between the oscillatory circuit and the MVM circuitry; and oscillator and MVM circuitry that are independent and interchangeable, and enhance the flexibility and circuit optimization capabilities of AIMC circuit designs.

In example embodiments, the mapping of the given weight to the duty cycle further comprises mapping the given weight to a conductance and mapping the conductance to the duty cycle. The technical benefits include a technique for implementing weights of the oscillatory matrix-vector multiplication device.

In one aspect, an oscillatory matrix-vector multiplication device comprises one or more oscillatory matrix-vector multiplication circuits, each oscillatory matrix-vector multiplication circuit comprising a first tunable resistive circuit comprising a first complementary metal-oxide semiconductor (CMOS) transistor 254-1, 404, a first activation input, and a first tunable resistive circuit output, wherein the first complementary metal-oxide semiconductor (CMOS) transistor 254-1, 404 comprises a first gate input, a first input coupled to the first activation input and a first output coupled to the first tunable resistive circuit output, and wherein the first activation input is configured to receive an activation signal; and a programmable oscillator circuit 420 coupled to the first gate input of the first tunable resistive circuit and configured to produce a control signal based on a given conductance. The technical benefits include an oscillatory AIMC circuit for matrix-vector multiplication (MVM) using transmission gates, switched capacitor circuitry and the like where an oscillator is applied to the gate(s) of the transistors of the MVM circuitry to implement a given conductance; usage of high input impedance gates for incorporating the oscillatory circuit into the AIMC circuit to provide independence between the oscillatory circuit and the MVM circuitry; and oscillator and MVM circuitry that are independent and interchangeable, and enhance the flexibility and circuit optimization capabilities of AIMC circuit designs.

In example embodiments, the first tunable resistive circuit comprises a parallel complementary metal-oxide semiconductor (CMOS) transistor 254-2 coupled in parallel with the first complementary metal-oxide semiconductor transistor 254-1, 404. The technical benefits include an improved oscillatory AIMC circuits for matrix-vector multiplication (MVM) where an oscillator is applied to the gate(s) of the transistors of the MVM circuitry to implement a given conductance.

In example embodiments, the first tunable resistive circuit comprises a serial complementary metal-oxide semiconductor (CMOS) transistor 304-2, wherein the serial complementary metal-oxide semiconductor (CMOS) transistor 304-2 comprises a serial gate input, a serial input and a serial output coupled to the first output, and a capacitor 308, a first terminal of the capacitor 308 coupled to the first output of the first complementary metal-oxide semiconductor (CMOS) transistor 254-1 and to the serial input of the second complementary metal-oxide semiconductor (CMOS) transistor 304-2. The technical benefits include an improved oscillatory AIMC circuit for matrix-vector multiplication (MVM) using transmission gates, switched capacitor circuitry and the like where an oscillator is applied to the gate(s) of the transistors of the MVM circuitry to implement a given conductance.

In example embodiments, the programmable oscillator circuit 420 comprises a resistor-capacitor circuit, wherein a resistor of the resistor-capacitor circuit is implemented with an analog memory device. The technical benefits include a mechanism for implementing a time constant that controls a duty cycle of the oscillator circuit 420.

In example embodiments, the programmable oscillator circuit 420 comprises a relaxation oscillator, wherein a resistance of the relaxation oscillator is implemented with an analog memory device and determines the duty cycle. The technical benefits include an improved mechanism for controlling a duty cycle of the oscillator.

In example embodiments, the programmable oscillator circuit comprises a phase change memory (PCM) device. The technical benefits include high component density, lower power requirements, large conductance range, improved conductance stability, high endurance (can be rewritten to new values) and ease of programming.

In example embodiments, the activation signal is pulse-code modulated. The technical benefits include an improved technique for encoding the activation signals.

In example embodiments, the control signal is based on a specified duty cycle. The technical benefits include an improved technique for implementing a given weight in the oscillatory AIMC circuit.

In example embodiments, the control signal is based on a variable resistance-capacitance delay. The technical benefits include a mechanism for controlling a duty cycle of the oscillator.

In example embodiments, each oscillatory matrix-vector multiplication circuit further comprises a second tunable resistive circuit comprising a second complementary metal-oxide semiconductor (CMOS) transistor 256-1, 406, a second activation input, and a second tunable resistive circuit output, wherein the second complementary metal-oxide semiconductor (CMOS) transistor 256-1, 406 comprises a second gate input, a second input coupled to the second activation input and a second output coupled to the second tunable resistive circuit output, wherein the second activation input is configured to receive the activation signal and wherein the programmable oscillator circuit 420 is coupled to the second gate input of the second tunable resistive circuit. The technical benefits include a technique for implementing a differential version of the oscillatory AIMC circuit.

In example embodiments, the first tunable resistive circuit comprises a parallel complementary metal-oxide semiconductor (CMOS) transistor 254-2 coupled in parallel with the first complementary metal-oxide semiconductor transistor 254-1 and the second tunable resistive circuit comprises a parallel complementary metal-oxide semiconductor (CMOS) transistor 256-2 coupled in parallel with the second complementary metal-oxide semiconductor transistor 256-1. The technical benefits include an improved oscillatory AIMC circuit for matrix-vector multiplication (MVM) where an oscillator is applied to the gate(s) of the transistors of the MVM circuitry to implement a given conductance.

In example embodiments, the first tunable resistive circuit comprises a first serial complementary metal-oxide semiconductor (CMOS) transistor 304-2 and a first capacitor 308; wherein the second tunable resistive circuit comprises a second serial complementary metal-oxide semiconductor (CMOS) transistor 306-2 and a second capacitor 310; wherein the first serial complementary metal-oxide semiconductor (CMOS) transistor 304-2 comprises a first serial gate input, a first serial input and a first serial output coupled to the first tunable resistive circuit output; wherein the second serial complementary metal-oxide semiconductor (CMOS) transistor 306-2 comprises a second serial gate input, a second serial input and a second serial output coupled to the second tunable resistive circuit output; wherein a first terminal of the first capacitor 308 is coupled to the first output of the first transistor complementary metal-oxide semiconductor (CMOS) transistor 254-1 and to the first serial input of the second complementary metal-oxide semiconductor (CMOS) transistor 304-2; and wherein a first terminal of the second capacitor 310 is coupled to the second output of the second transistor complementary metal-oxide semiconductor (CMOS) transistor 254-1 and to the second serial input of the second complementary metal-oxide semiconductor (CMOS) transistor 306-2. The technical benefits include an improved oscillatory AIMC circuit for matrix-vector multiplication (MVM) using transmission gates, switched capacitor circuitry and the like where an oscillator is applied to the gate(s) of the transistors of the MVM circuitry to implement a given conductance.

In one aspect, an oscillatory matrix-vector multiplication device comprises an array 448 of a plurality of oscillatory matrix-vector multiplication circuits, the array 448 configured as a plurality of columns and a plurality of rows of the oscillatory matrix-vector multiplication circuits, each oscillatory matrix-vector multiplication circuit comprising a first tunable resistive circuit comprising a first complementary metal-oxide semiconductor (CMOS) transistor 254-1, 404, a first activation input, and a first tunable resistive circuit output, wherein the first complementary metal-oxide semiconductor (CMOS) transistor 254-1, 404 comprises a first gate input, a first input coupled to the first activation input and a first output coupled to the first tunable resistive circuit output; a second tunable resistive circuit comprising a second complementary metal-oxide semiconductor (CMOS) transistor 256-1, 406, a second activation input, and a second tunable resistive circuit output, wherein the second complementary metal-oxide semiconductor (CMOS) transistor 256-1, 406 comprises a second gate input, a second input coupled to the second activation input and a second output coupled to the second tunable resistive circuit output; a programmable oscillator circuit 420 coupled to the first gate input of the first tunable resistive circuit and coupled to the second gate input of the second tunable resistive circuit and wherein the programmable oscillator circuit 420 is configured to produce a control signal based on a given conductance; and a plurality of summation circuits 440, wherein the first input of each first tunable resistive circuit in a given row of the array 448 and the second input of each second tunable resistive circuit in the given row of the array 448 are coupled to an activation signal corresponding to the row, wherein the first tunable resistive circuit output of each first tunable resistive circuit in a given column of the array 448 are coupled together and the second tunable resistive circuit output of each second tunable resistive circuit in the given column of the array 448 are coupled together and wherein one of the plurality of summation circuits 440 is configured to subtract a current on the coupled second tunable resistive circuit outputs of the second tunable resistive circuits in the given column of the array 448 from the coupled first tunable resistive circuit outputs of the first tunable resistive circuits in the given column of the array 448. The technical benefits include oscillatory AIMC circuits for matrix-vector multiplication (MVM) using transmission gates, switched capacitor circuitry and the like where an oscillator is applied to the gate(s) of the transistors of the MVM circuitry to implement a given conductance; usage of high input impedance gates for incorporating the oscillatory circuit into the AIMC circuit to provide independence between the oscillatory circuit and the MVM circuitry; oscillator and MVM circuitry that are independent and interchangeable, and enhance the flexibility and circuit optimization capabilities of AIMC circuit designs; and an array of circuitry to perform matrix-vector multiplication in an efficient manner.

In example embodiments, the array 448 includes input peripheral circuitry 444 for generating the activation signals based on input data, the input peripheral circuitry 444 coupled to the first tunable resistive circuit and the second tunable resistive circuit; output peripheral circuitry 452 for generating an inferencing result based on outputs of the plurality of summation circuits 440, the output peripheral circuitry 452 coupled to the first tunable resistive circuit and the second tunable resistive circuit; and a controller 456 for coordinating an inferencing operation using the oscillatory matrix-vector multiplication device. The technical benefits include circuitry for performing inferencing operations using the oscillatory AIMC circuits.

In one aspect, a hardware description language (HDL) design structure encoded on a machine-readable data storage medium, the HDL design structure comprising elements that when processed in a computer-aided design system generates a machine-executable representation of a semiconductor structure, wherein the HDL design structure comprises an oscillatory matrix-vector multiplication device comprises one or more oscillatory matrix-vector multiplication circuits, each oscillatory matrix-vector multiplication circuit comprising a first tunable resistive circuit comprising a first complementary metal-oxide semiconductor (CMOS) transistor 254-1, 404, a first activation input, and a first tunable resistive circuit output, wherein the first complementary metal-oxide semiconductor (CMOS) transistor 254-1, 404 comprises a first gate input, a first input coupled to the first activation input and a first output coupled to the first tunable resistive circuit output, and wherein the first activation input is configured to receive an activation signal; and a programmable oscillator circuit 420 coupled to the first gate input of the first tunable resistive circuit and configured to produce a control signal based on a given conductance.

Techniques as disclosed herein can provide substantial beneficial technical effects. Some embodiments may not have these potential advantages and these potential advantages are not necessarily required of all embodiments. By way of example only and without limitation, one or more embodiments may provide one or more of:
oscillatory AIMC circuits for matrix-vector multiplication (MVM) using transmission gates, switched capacitor circuitry and the like where an oscillator is applied to the gate(s) of the transistors of the MVM circuitry to implement a given conductance;
usage of high input impedance gates for incorporating the oscillatory circuit into the AIMC circuit to provide independence between the oscillatory circuit and the MVM circuitry; and
oscillator and MVM circuitry that are independent and interchangeable, and enhance the flexibility and circuit optimization capabilities of AIMC circuit designs.

Non-von Neumann architectures based on analog in-memory compute (AIMC) can substantially improve the throughput and energy efficiency of matrix vector multiplication (MVM) in neural networks. Most conventional architectures fall into two classes:
1) analog memory based on direct current (DC) circuitry, in which instantaneous current or accumulated current is measured using an analog-to-digital converter (ADC) (activations are applied using digital-to-analog converters (DACs) or pulse-width modulators (PWMs)); and
2) more mature memory circuitry, such as static random-access memory (SRAM), in which MVM is computed via charge sharing.

In example embodiments, oscillatory AIMC for MVM is disclosed using transmission gates, switched capacitor circuitry, and the like, where an oscillator is applied to the gate(s) of the corresponding circuit. The high input impedance of the gate(s) means the oscillatory circuit is independent from the MVM circuitry. The oscillator and MVM circuitry become independent and interchangeable, and enhance flexibility and circuit optimization capabilities.

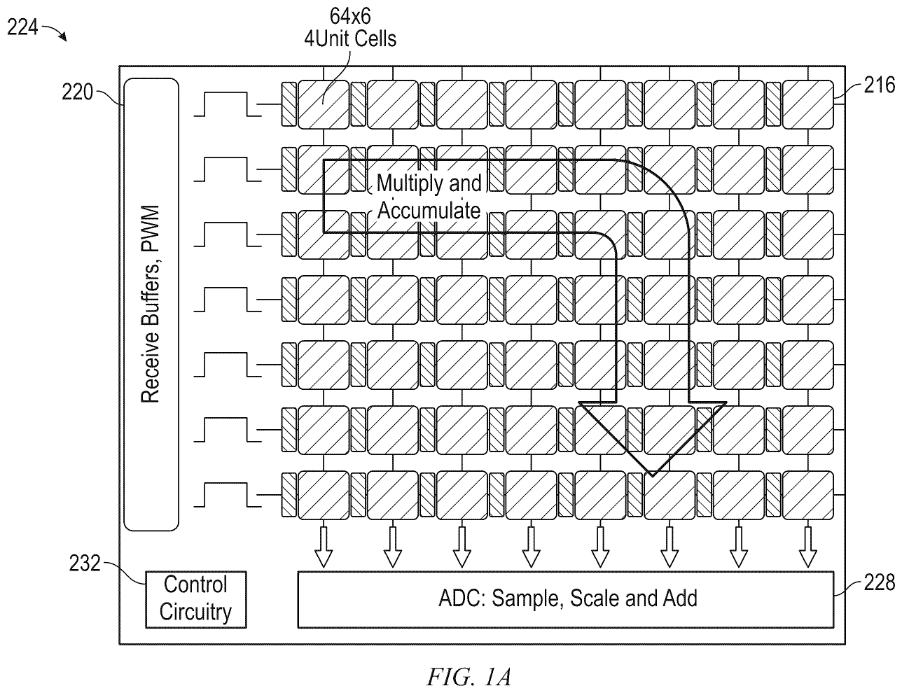

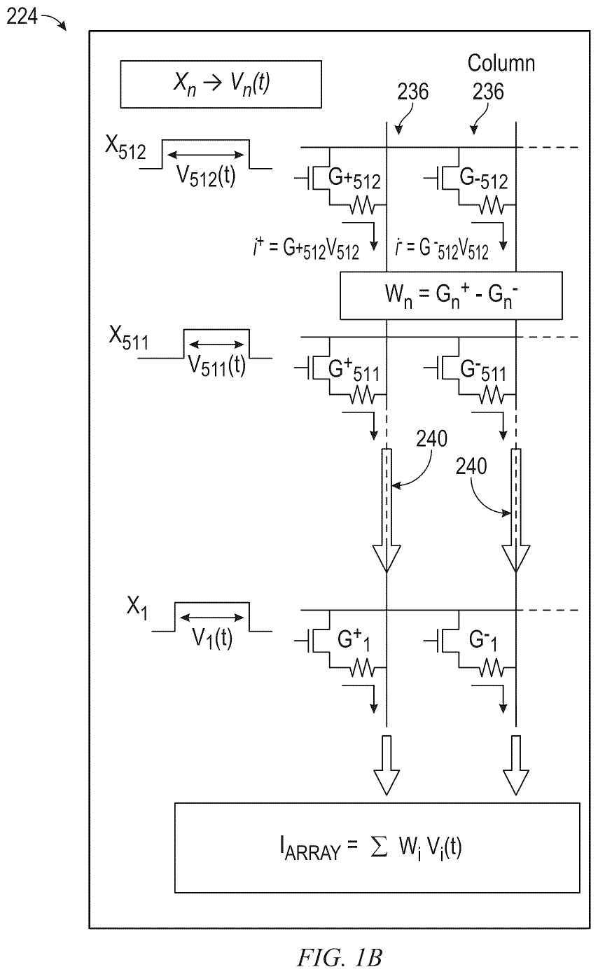

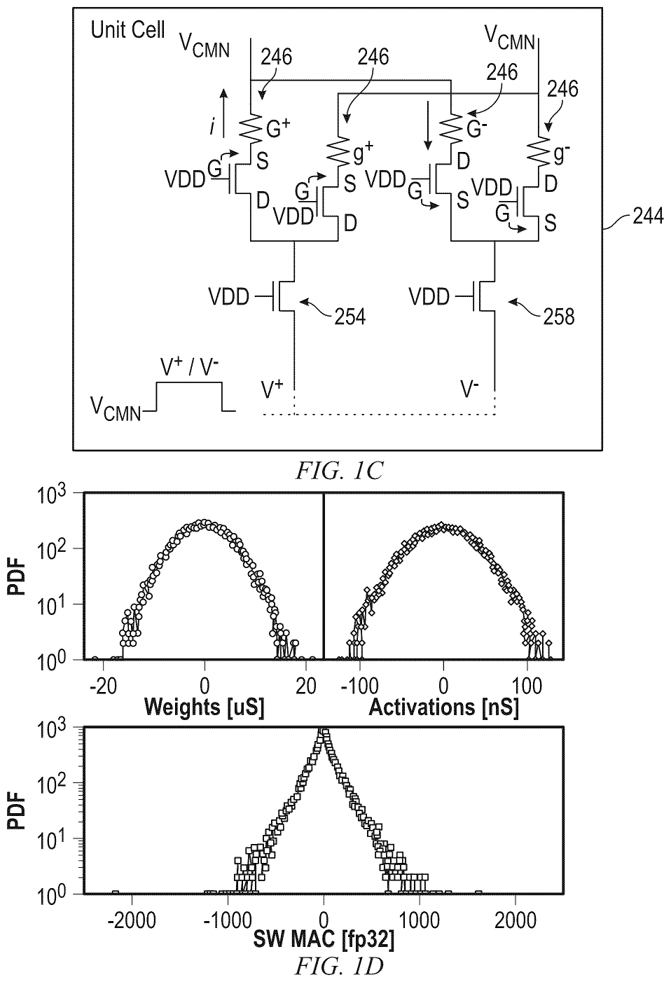

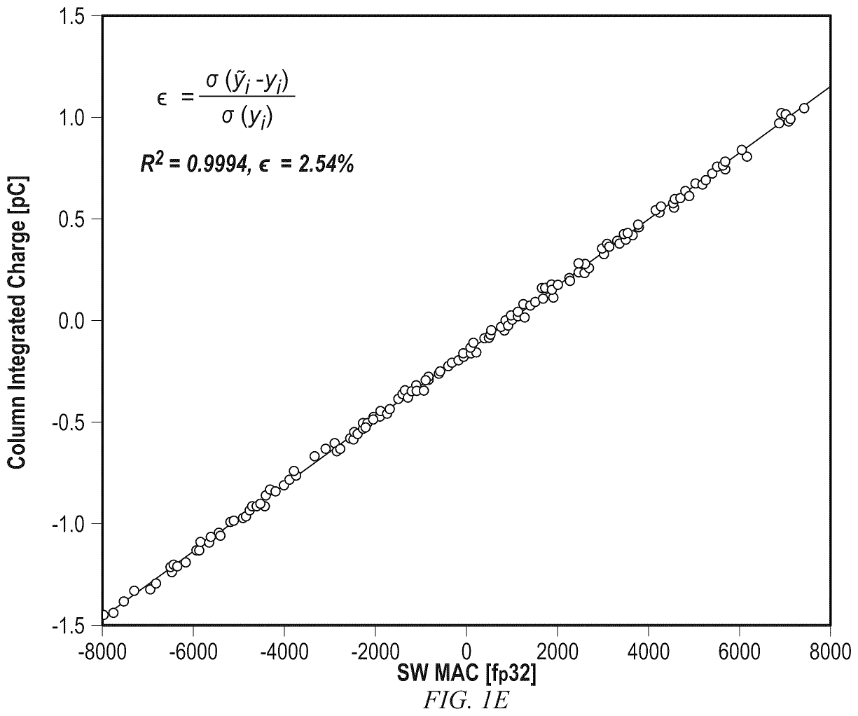

FIG. 1A illustrates a conventional architecture for performing a multiply and accumulate operation. Receive buffers 220 receive pulse-width modulated activations 224 and forward the activations 224 to corresponding analog in-memory compute devices 216. Each analog in-memory compute device 216 implements a weight that is multiplied by the input activation 224 (as defined by the pulse width of the corresponding signal) by the analog in-memory compute device 216. An ADC circuit 228 sums (accumulates) the multiplication results of each column of the matrix of analog in-memory compute devices 216 under the control of the control circuitry 232.

FIG. 1B illustrates a conventional circuit diagram for performing a multiply and accumulate operation. As in FIG. 1A, activations 224 are encoded using pulse-width modulation and the activations 224 are forwarded to corresponding analog in-memory compute devices 236 implemented with a tunable resistance. Each analog in-memory compute device 236 implements a weight that is multiplied by the input activation 224 by the analog in-memory compute device 236. The currents 240 produced by each analog in-memory compute device 236 in a column of the matrix of the analog in-memory compute devices 236 are summed (accumulated) to generate the multiplication results of each column.

FIG. 1C illustrates a conventional unit cell circuit diagram of an analog in-memory compute device 244 for performing a multiply and accumulate operation. An activation is pulse-code modulated and provided as input to the V^{+¿¿} and V^{-¿¿} terminals. Tunable resistors 246 are programmed with the given conductance. The unit cell circuit of FIG. 1C can be operated in various modes. In a first mode of operation, the gate terminals of the select transistors 254, 258 are first held high, as illustrated in FIG. 1C. Then, a voltage potential is created across the unit cell circuit by holding one end at the common read voltage (V_{CMN}), while the other end is tied to a select transistor 254, 258 whose drain is held to V+ or V− (depending on the sign of the activation), for the duration of the pulse-width modulated activation, as depicted in FIG. 1C. For a zero activation, or after the given duration, the drains of the select transistors 254, 258 are brought to V_{CMN}, thus creating no voltage potential across the unit cell circuit and producing zero current.

In a second mode of operation, the drains of the select transistors 254, 258 are kept at V+/V− (depending on the sign of the activation, where FIG. 1C depicts a positive activation). In this mode of operation, the pulse-width modulated activations are instead driven to the gates of the select transistors 254, 258. While the gates of the transistors 254, 258 are held high for the duration of the pulse-width modulated activation, a voltage potential is inherently created across the unit cell circuit. For a zero activation, or after the given duration, the gates of the select transistors 254, 258 are pulled low thereby “disconnecting” the unit cell circuit from V+ and V− (rather than tying it to V_{CMN}), and thereby producing zero current.

FIG. 1D shows graphs of the probability distribution functions of weights, activations and multiply-accumulate results drawn independently from each other, in accordance with example embodiments. The probability distribution functions were generated using PYTHON numpy.random.randn and other random number generators which mimic the behavior and distributions found in neural networks.

FIG. 1E is a graph of column integrated charge vs. multiply-accumulate results for the conventional AIMC circuit of FIG. 1B, in accordance with example embodiments. (The x-axis is the ideal MVM result and the y-axis is the simulated result of the example oscillatory AIMC circuit.) The experimental results (dots) show that the multiply-accumulate results are relatively proportional to the column integrated charge, as desired. The error ∈ is 2.54%.

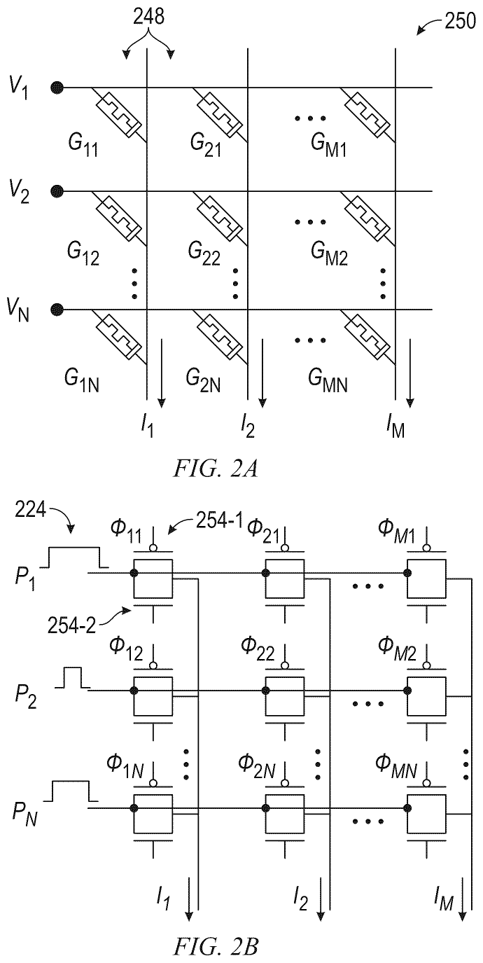

FIG. 2A illustrates an array of conductances for a conventional AIMC MVM implementation. FIG. 2B illustrates a first embodiment of an oscillatory AIMC for MVM, in accordance with an aspect of the invention. The conductances 248 of the multiply-and-accumulate (MAC) matrix 250 are implemented using a pair of CMOS transistors 254-1, 254-2. Activations 224 encoded using pulse-width modulation are applied to the source terminals of the CMOS transistors 254-1, 254-2. An oscillating signal, such as oscillating signal φ₁₁, is applied to the gate of the CMOS transistor 254-1 and an inverted version of the oscillating signal is applied to the gate of the CMOS transistor 254-2. The weight of the corresponding cell is set by setting a duty cycle of the oscillating signal; that is, G_{MN} is determined by the switching frequency φ_{MN} (phase differences are not relevant due to the effect of averaging when many oscillations are permitted per MVM operation). A small weight is set by using a duty cycle where the signal is high for a relatively short period of time and a large weight is set by using a duty cycle where the signal is high for a relatively long period of time. Thus, a small weight will pass the activation signal 224 through the CMOS transistors 254-1, 254-2 for a shorter period of time than a larger weight. The conductance is thus modulated. It is noted that, during one cycle of the activation signal 224, one or more cycles of the oscillating signal φ₁₁ may be applied. For example, five cycles of the oscillating signal φ₁₁ may be applied during one cycle of the activation signal 224. Thus, G_{MN} is essentially averaged over many switches of the oscillating signal φ₁₁. The MVM fidelity can be evaluated using an ideal φ_{MN}, as described further below.

More generally, the weight is set based on a resistor-capacitor (RC) time constant associated with the RC delay circuitry. Here, a small resistance (large analog conductance) yields a faster ramp up time and turns on the transistor(s) faster, allowing more current to pass and thereby configuring a large weight. A high resistance ramps the voltage more slowly causing the transistor(s) to turn on less quickly, thereby configuring a smaller weight. Moreover, example embodiments inherently enable weights equal to zero to be programmed.

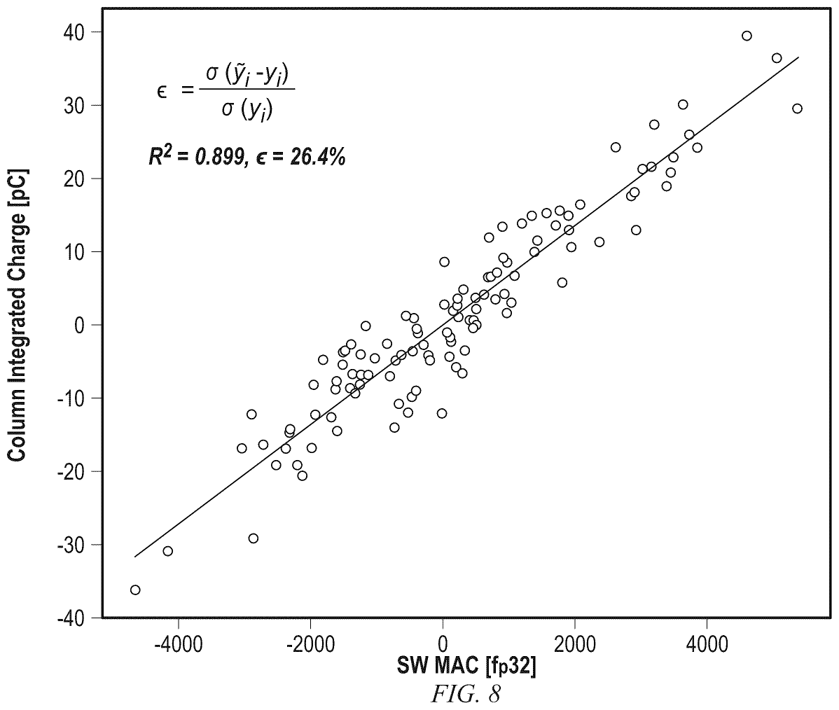

For single oscillation MVMs, minor phase differences should likely be taken into account, depending on the operating speed, in order to minimize the error in the MVM accuracy (as shown in FIG. 8). In this case, to further optimize the single oscillation MVMs, additional timing calibration circuitry that determines when each weight oscillation should begin (likely one calibration factor per column since all weights within a column are the same distance from the PWM circuitry) can be implemented.

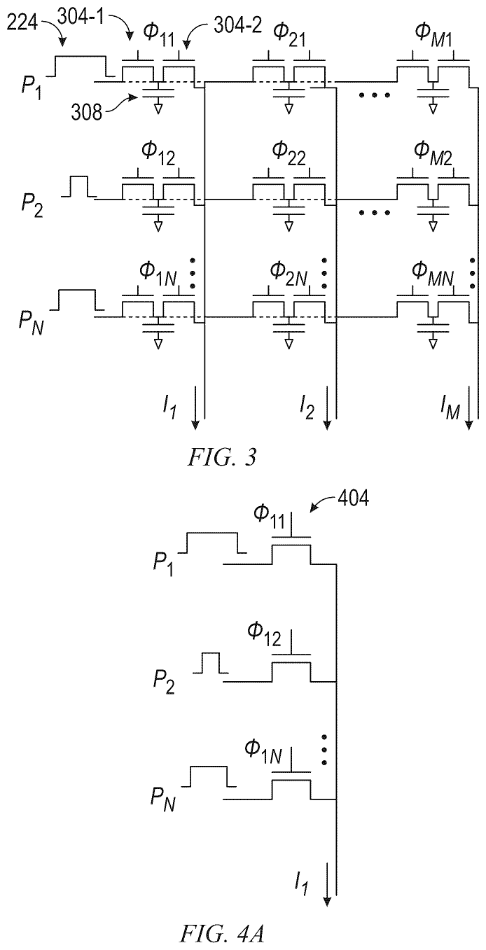

FIG. 3 illustrates a second embodiment of an oscillatory AIMC for MVM, in accordance with example embodiments. The conductances 248 of the MAC matrix 250 are implemented using a pair of CMOS transistors 304-1, 304-2 in conjunction with a capacitor 308. Activations 224 encoded using pulse-width modulation are applied to a source terminal of the CMOS transistor 304-1. An oscillating signal is applied to the gate of the CMOS transistor 304-1 and an inverted version of the oscillating signal is applied to the gate of the CMOS transistor 304-2. The weight of the corresponding cell is set by setting a duty cycle of the oscillating signal, as described above. A small weight is set by using a duty cycle where the signal is high for a relatively short period of time and a large weight is set by using a duty cycle where the signal is high for a relatively long period of time. While the corresponding activation 224 is high, a small weight will pass the activation signal 224 through the CMOS transistor 304-1 for a shorter period of time than a larger weight and thereby will charge the capacitor 308 for a shorter period of time in comparison to a larger weight.

The inversion of the oscillating signal applied to the gate of the CMOS transistor 304-2 has the effect of turning off the CMOS transistor 304-2 while the CMOS transistor 304-1 is turned on and the capacitor 308 is charging. Then, during the low portion of the duty cycle, the CMOS transistor 304-1 is turned off and the CMOS transistor 304-2 is turned on to allow the charged value to be read by discharging the capacitor 308 (transferring current). The charge that is transferred to the capacitor 308 is therefore based on the duration of the activation pulse and the duty cycle of the oscillating signal. Since the charging of the capacitor 308 only occurs while the input activation is high and the oscillating signal is above the threshold voltage of the CMOS transistor 304-1, the multiplication operation between the activation and the weight is effectively enabled.

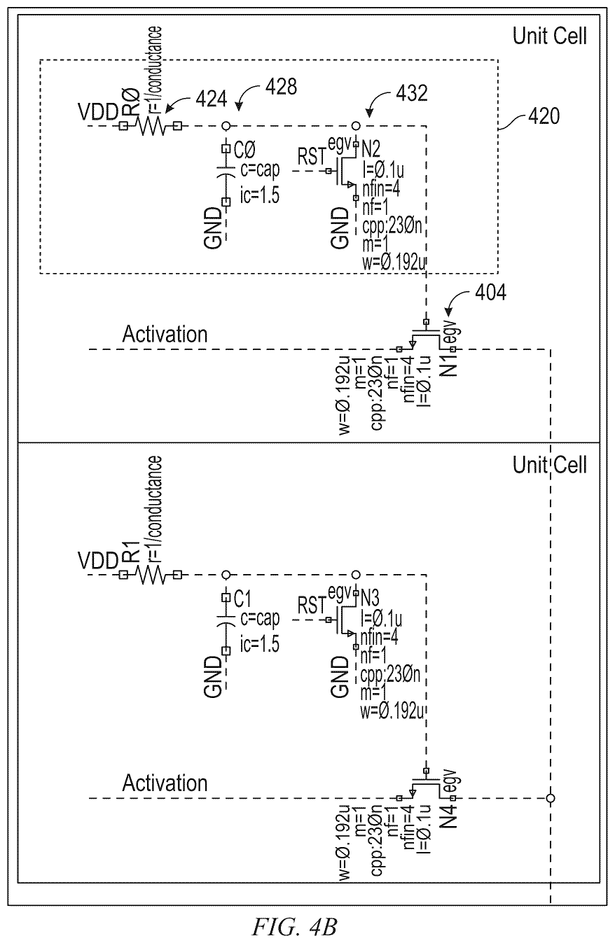

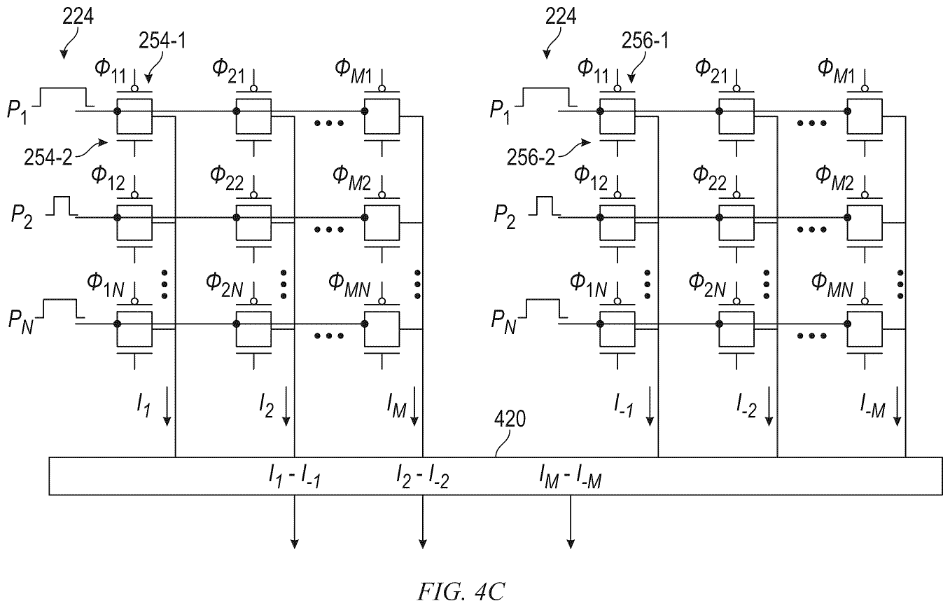

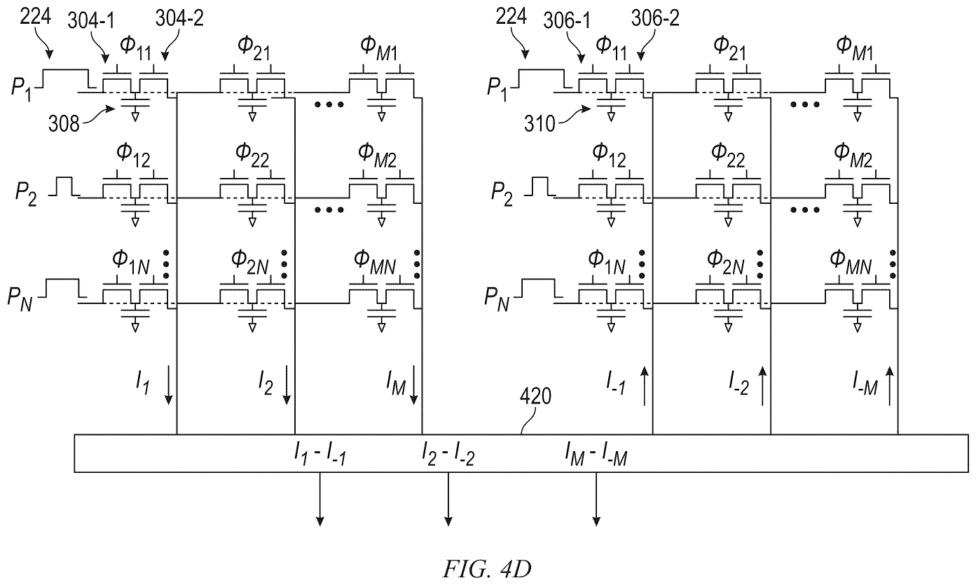

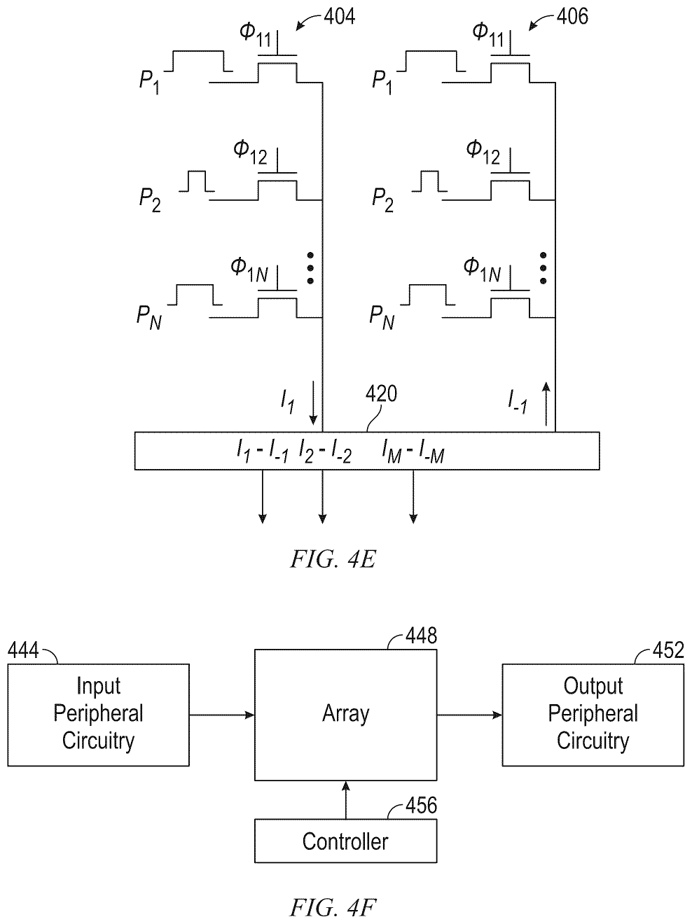

FIG. 4A illustrates a third embodiment of an oscillatory AIMC for MVM, in accordance with example embodiments. The oscillatory AIMC of FIG. 4A is similar to the oscillatory AIMC of FIG. 2B, except the pair of CMOS transistors 254-1, 254-2 is replaced by a single transistor 404. (The PMOS transistor 254-2 of FIG. 2B can be removed because the ADC is held at ground voltage and only the NMOS transistor 254-1 will be needed. It is noted that only one column of the MVM (array) circuitry is illustrated in FIG. 4A.) FIG. 4B illustrates a circuit diagram for the example oscillatory AIMC of FIG. 4A integrated with the oscillator circuit 420, in accordance with example embodiments. The oscillating signal φ₁₁ is generated by a resistor-capacitor (RC) circuit of the oscillator circuit 420 that includes a tunable resistor 424 and a capacitor 428. The capacitor 428 charges at a rate determined by the resistance of the tunable resistor 424. In an example embodiment, the capacitor 428 is 1 femtofarad (fF) and the oscillation frequency is 2 Gigahertz (GHz). The resistance of the tunable resistor 424 is selected based on the desired weight of the cell, as described more fully below. A transistor 432 resets the charge on the capacitor 428 when the reset signal RST is activated. The transistor 432 will have lower resistance than non-volatile memory (NVM), so the RC time constant of the reset circuit will be much faster. In example embodiments, the reset signal RST should be generated using a fast clock (such as a 2 GHz clock) to ensure that the charging of the capacitor 428 cuts-off at the correct time. If the reset signal RST must propagate over an extended distance to oscillatory AIMCs, known techniques may be utilized to mitigate the difference in phase of the reset signal RST observed by each of the AIMCs. Since fast charging with a small capacitor 428 is desired, in example embodiments, a metal-oxide-semiconductor (MOS) capacitor is used in place of a metal-insulator-metal (MIM) capacitor. In the example embodiment of FIGS. 4A-4B, the activations (X) were sampled from X |(N(μ=0, σ=35 ns))| and the conductances (G) were sampled from G |(N(μ=0, σ=5 uS))|. It is noted that, in example embodiments, the analog output of the oscillator circuit 420 may be converted to a square wave by, for example, passing the analog output of the oscillator circuit 420 through a digital buffer having a similar threshold voltage as the CMOS transistor being driven by the oscillator circuit 420, such as the CMOS transistor 404.

FIG. 4C illustrates a fourth embodiment of an oscillatory AIMC for MVM, in accordance with example embodiments. The oscillatory AIMC for MVM of FIG. 4C is a differential version of the oscillatory AIMC for MVM of FIG. 2B. In the example embodiment of FIG. 4C, the circuit of FIG. 2B is replicated and configured in a differential mode. In particular, similar to the differential circuit of FIG. 1C, activations 224 encoded using pulse-width modulation are applied to the source terminals of the CMOS transistors 254-1, 254-2, 256-1, 256-2. An oscillating signal, such as oscillating signal φ₁₁, is applied to the gate of the CMOS transistors 254-1, 256-1. The weights of the corresponding cell are set by setting a duty cycle of the oscillating signal; that is, G_{MN} is determined by the switching frequency φ_{MN} (phase differences are not relevant due to the effect of averaging when many oscillations are permitted per MVM operation). In example embodiments, the currents produced by corresponding columns of the oscillatory AIMC are combined using combiner 440 by generating, for example, I₁-I₋₁ for the first column, I₂-I₋₂ for the second column, and so on, and are provided as outputs of the oscillatory AIMC.

FIG. 4D illustrates a fifth embodiment of an oscillatory AIMC for MVM, in accordance with example embodiments. The oscillatory AIMC for MVM of FIG. 4D is a differential version of the oscillatory AIMC for MVM of FIG. 3. In the example embodiment of FIG. 4D, the circuit of FIG. 3 is replicated and configured in a differential mode. The conductances 248 of the MAC matrix 250 are implemented using two pairs of CMOS transistors 304-1, 304-2, 306-1, 306-2 in conjunction with corresponding capacitors 308, 310. In particular, similar to the differential circuit of FIG. 1C, activations 224 encoded using pulse-width modulation are applied to source terminals of CMOS transistors 304-1, 306-1. An oscillating signal is applied to the gates of the CMOS transistors 304-1, 306-1. The weight of the corresponding cell is set by setting a duty cycle of the oscillating signal, as described above. In example embodiments, the currents produced by corresponding columns of the oscillatory AIMC are combined using combiner 440 by generating, for example, I₁-I₋₁ for the first column, I₂-I₋₂ for the second column, and so on, and are provided as outputs of the oscillatory AIMC.

FIG. 4E illustrates a sixth embodiment of an oscillatory AIMC for MVM, in accordance with example embodiments. The oscillatory AIMC for MVM of FIG. 4E is a differential version of the oscillatory AIMC for MVM of FIG. 4A. As described above, the oscillatory AIMC of FIG. 4A is similar to the oscillatory AIMC of FIG. 2B, except the pair of CMOS transistors 254-1, 254-2 is replaced by a single transistor 404. (It is noted that only one column of the MVM circuitry is illustrated in FIG. 4A.) In the example embodiment of FIG. 4E, the circuit of FIG. 4A is replicated and configured in a differential mode. In particular, similar to the differential circuit of FIG. 1C, activations 224 encoded using pulse-width modulation are applied to the source terminals of the CMOS transistors 404, 406. In example embodiments, the currents produced by corresponding columns of the oscillatory AIMC are combined using combiner 440 by generating, for example, I₁-I₋₁ for the first column, I₂-I₋₂ for the second column, and so on, and are provided as outputs of the oscillatory AIMC.

FIG. 4F illustrates an example system for performing inferencing using an array 448 of oscillatory AIMCs for MVM, in accordance with example embodiments. In example embodiments, the system of FIG. 4F includes an array 448 of a plurality of oscillatory matrix-vector multiplication circuits, the array 448 configured as a plurality of columns and a plurality of rows of the oscillatory matrix-vector multiplication circuits, each oscillatory matrix-vector multiplication circuit that includes a first tunable resistive circuit that includes a first complementary metal-oxide semiconductor (CMOS) transistor 254-1, 404, a first activation input, and a first tunable resistive circuit output, wherein the first complementary metal-oxide semiconductor (CMOS) transistor 254-1, 404 comprises a first gate input, a first input coupled to the second activation input and a first output coupled to the first tunable resistive circuit output; and a second tunable resistive circuit that includes a second complementary metal-oxide semiconductor (CMOS) transistor 256-1, 406, a second activation input, and a second tunable resistive circuit output, wherein the second complementary metal-oxide semiconductor (CMOS) transistor 256-1, 406 includes a second gate input, a second input coupled to the second activation input and a second output coupled to the second tunable resistive circuit output. The example system also includes a programmable oscillator circuit 420 coupled to the first gate input of the first tunable resistive circuit and coupled to the second gate input of the second tunable resistive circuit. In example embodiments, the programmable oscillator circuit 420 is configured to produce a control signal based on a given conductance. Input peripheral circuitry 444 generates the activation signals based on input data. A plurality of summation circuits 440 generates outputs for output peripheral circuitry 452, and the output peripheral circuitry 452 generates an inferencing result based on outputs of the plurality of summation circuits 440. A controller 456 coordinates an inferencing operation using the oscillatory matrix-vector multiplication device.

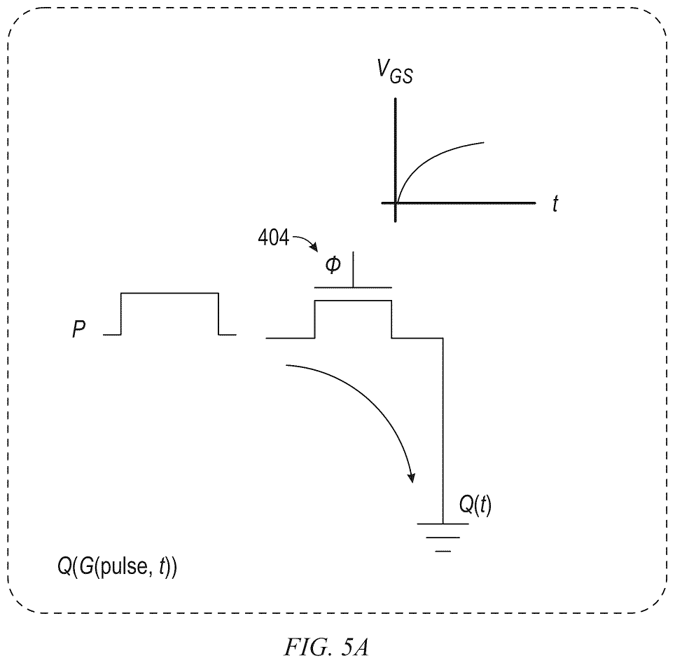

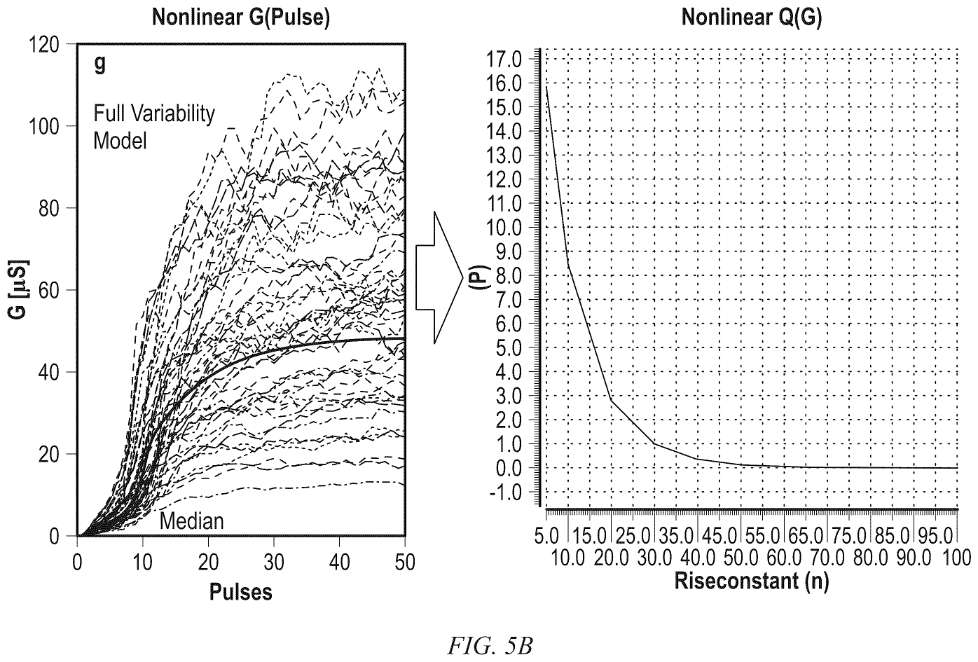

FIG. 5A illustrates a graph of the gate voltage V_{GS} for the transistor 404 while the tunable resistor 424 charges the capacitor 428, in accordance with example embodiments. As illustrated in FIG. 5A, the charging of the capacitor 428 is not linear. Therefore, the overall non-linearity of the charging of the capacitor 428 needs to be taken into account when mapping the desired weight for a cell to the duty cycle of the oscillating signal φ₁₁. Moreover, the current flowing through transistor 404 does not transition instantaneously from zero to the saturation current of the transistor 404, but is also non-linear.

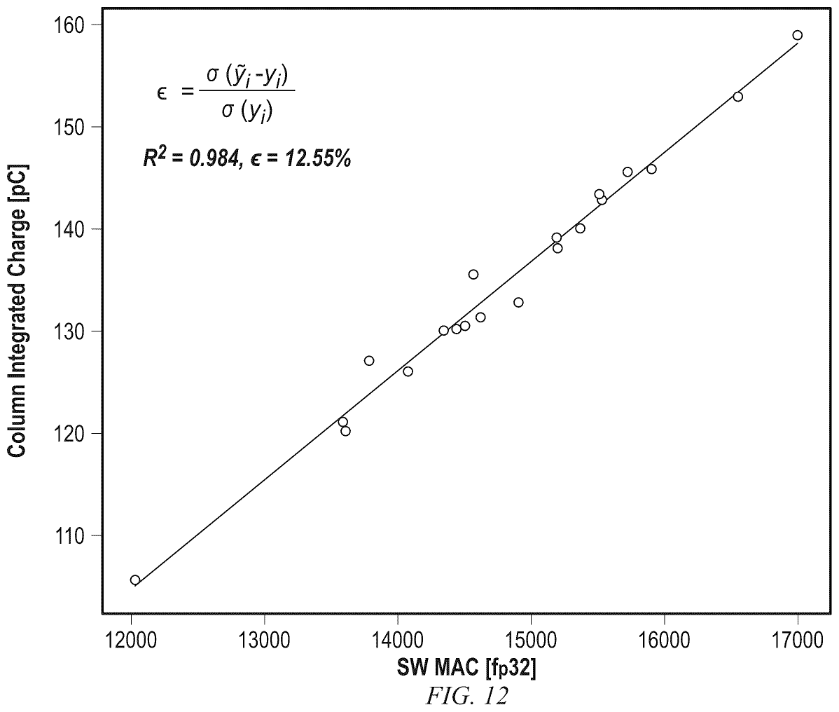

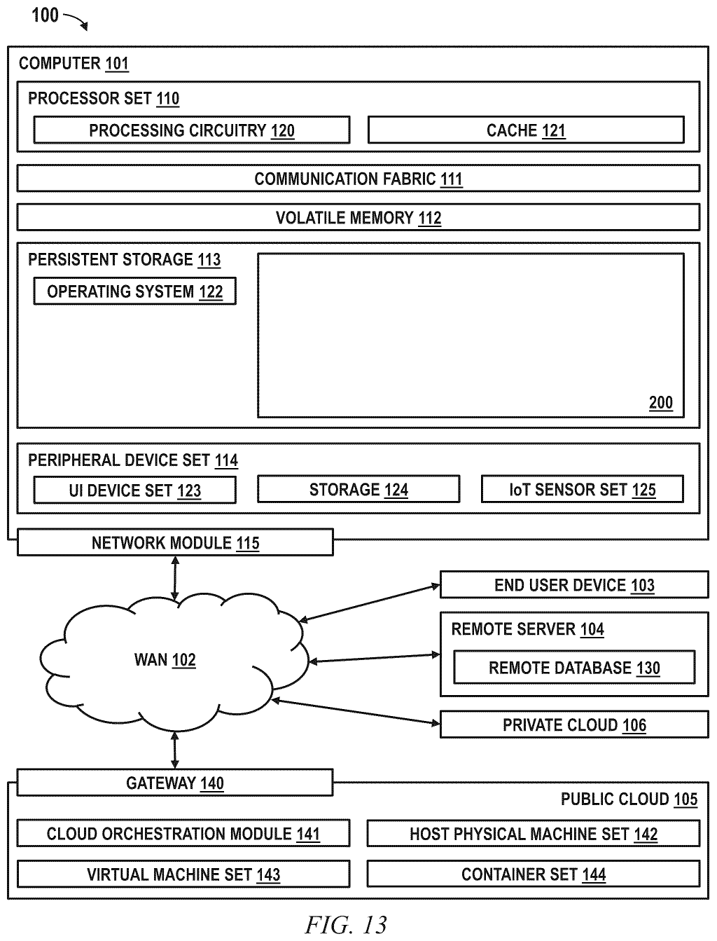

FIG. 5B illustrates graphs of nonlinear G and nonlinear Q, in accordance with example embodiments. FIG. 5B shows that NVM can be programmed to a limited conductance range and may have some nonlinearities and variability. These characteristics may need to be taken into consideration, as described herein. The second part Q(G), representing the charge as a function of the conductance G, simply shows that the behavior is non-linear, indicating that the conductances need to be programmed accordingly. This is similar to the nonlinear Q graph of FIG. 12.

### Transmission Gate MVM and Simulation Results

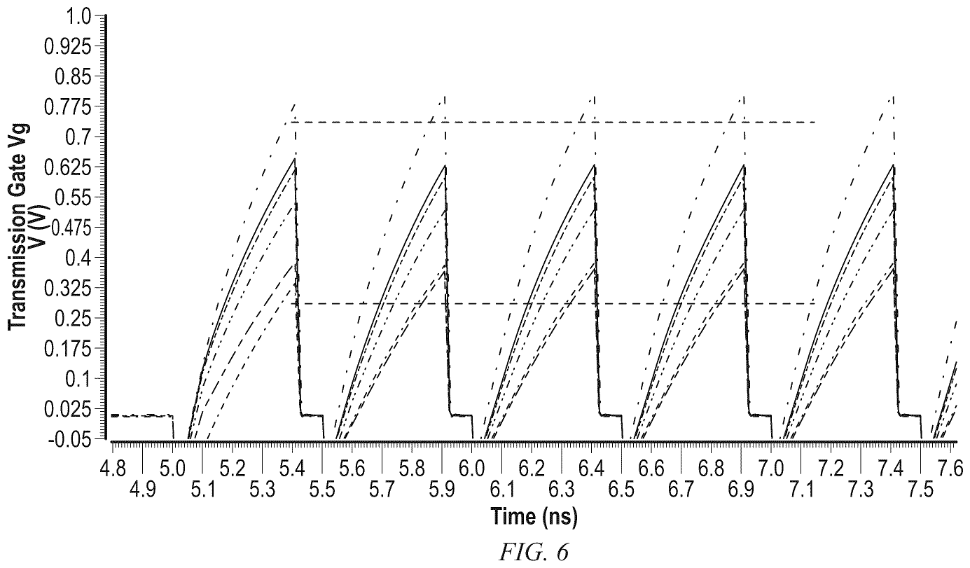

FIG. 6 illustrates six different duty cycles for five cycles, in accordance with example embodiments. The y-axis shows the transmission gate voltage Vg and the x-axis represents time. (The transmission gate approach was described above. FIG. 6 represents different amounts of charge passing through the “transmission gate” in the MVM circuitry.) As illustrated in FIG. 6, the charging of the capacitor 428 is non-linear. In order to ensure that an accurate result is obtained, a plurality of cycles of the oscillating signal φ₁₁ is performed for each desired multiply accumulate operation (for example, the five cycles illustrated in FIG. 6). Varying the RC constant per unit cell drives the transmission gate voltage Vg of a respective transistor 404.

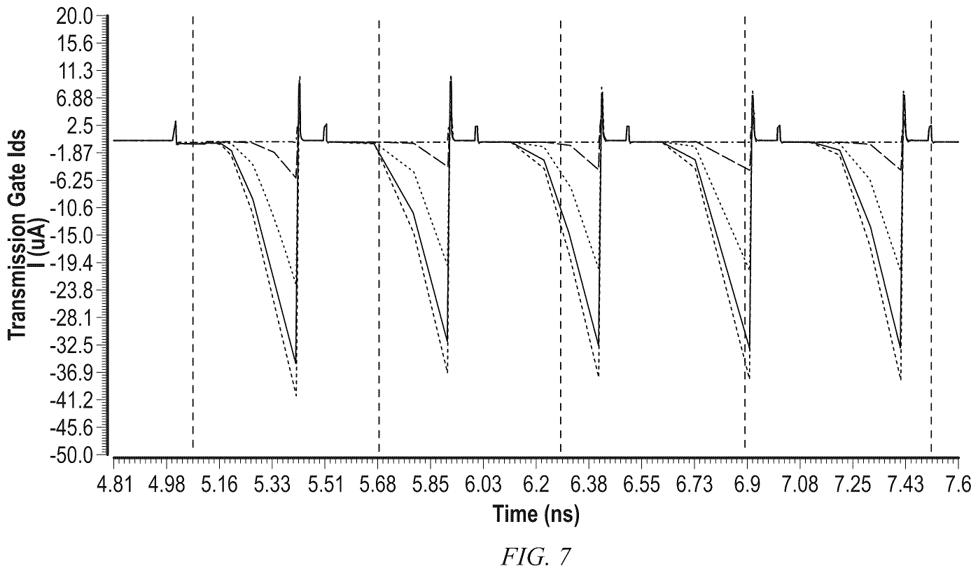

FIG. 7 illustrates the current, Ids, through the transistor 404 for six different duty cycles for 5 cycles, in accordance with example embodiments. The y-axis shows the current, Ids, through the transistor 404 and the x-axis represents time. After each cycle, the transistor 432 resets the charge on the capacitor 428, as illustrated by the five spikes following the charging in FIG. 7.

FIG. 8 is a graph of column integrated charge vs. ideal multiply-accumulate results, in accordance with example embodiments. The experimental results (dots) were generated using the transmission gate approach (using the single NMOS transistor per cell embodiment of FIG. 4A) and show that the multiply-accumulate results (x-axis) are relatively proportional to the column integrated charge (y-axis) (after compensation), as desired. The error ∈ is 26.44%.

### Transmission Gate MVM and Computerized Circuit Simulation

### Impact of PCM Voltage-Dependence

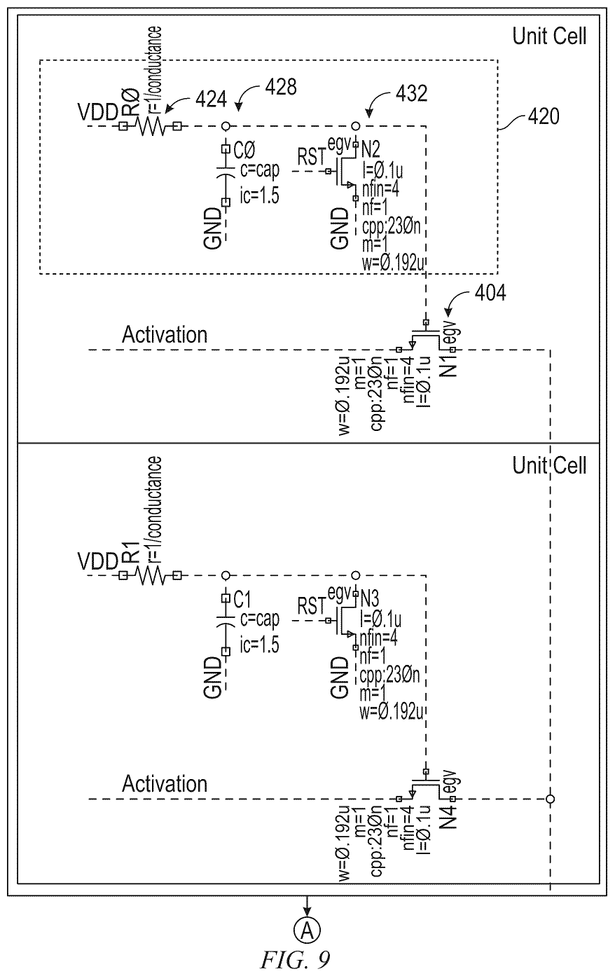

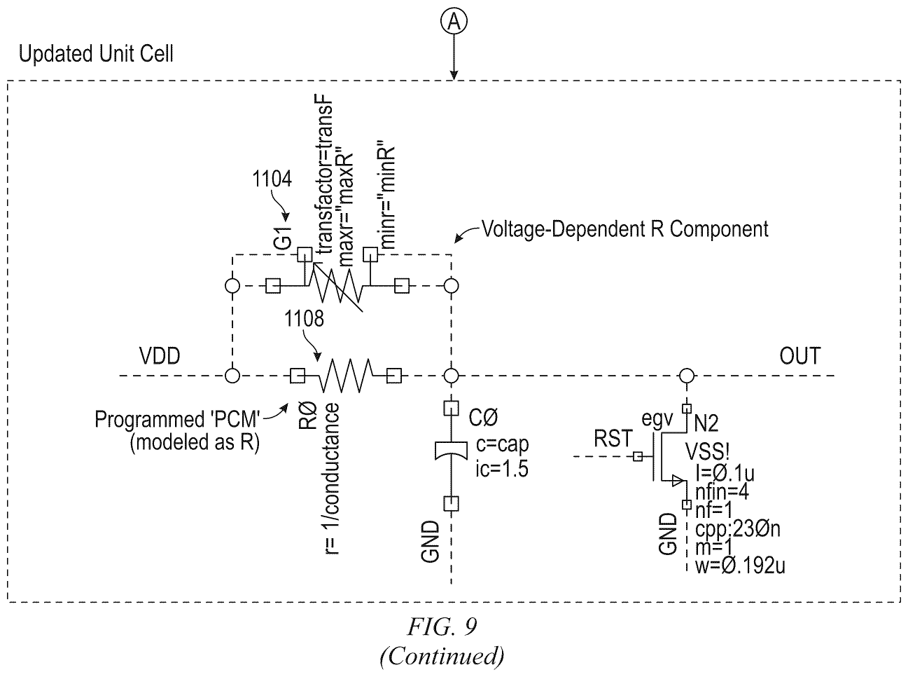

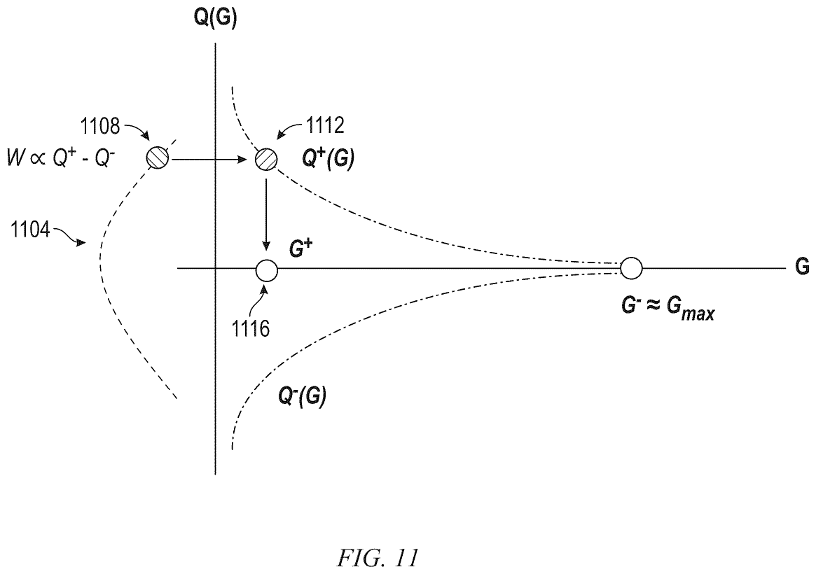

FIG. 9 illustrates a variation of the circuit of FIG. 4B configured to simulate the voltage-dependence of using a phase change memory (PCM) device 1108 with some degree of voltage-dependent conductance, in accordance with example embodiments. The conductivity of the circuit of FIG. 9 has voltage dependence when using the phase change memory device 1108 (the voltage across the PCM device 1108 is not constant due to charging, and the conductivity is therefore not constant). A voltage-dependent resistance component 1104 has therefore been incorporated into the circuit of FIG. 4B in parallel with the programmed PCM device 1108 to simulate such an effect. FIG. 11 is a graph of column integrated charge vs. ideal multiply-accumulate results for the circuit of FIG. 9, in accordance with example embodiments. The experimental results (dots) show that the ideal multiply-accumulate results (x-axis) are relatively proportional to the column integrated charge (y-axis) (after compensation), as desired. The error ∈ is 12.55%.

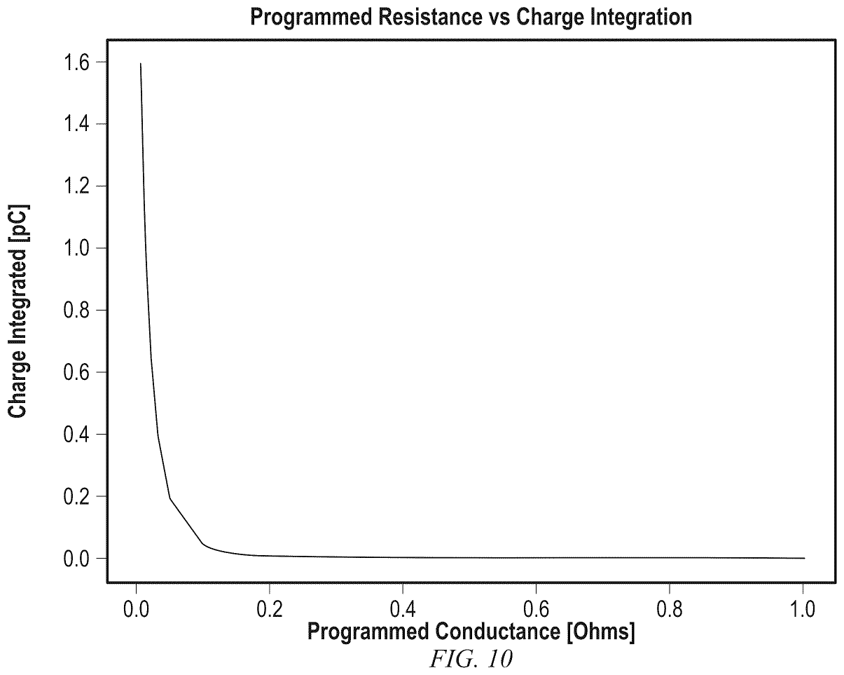

FIG. 10 is an example graph of integrated charge vs. programmed conductance, in accordance with example embodiments. As described above, the relationship of integrated charge and programmed conductance is non-linear. The mapping of conductance (weights) to the integrated charge needs to be determined and applied when utilizing an oscillatory MVM circuit. In particular, the duty cycle selected for the oscillator circuit should compensate for the non-linearities described above. Moreover, as illustrated in FIG. 10, the curve is relatively flat for programmed conductances greater than 0.2, meaning different conductances cannot be effectively distinguished based on the integrated charge.

FIG. 12 is a graph that illustrates a mapping of weights to conductances, in accordance with example embodiments. The distribution curve 1104 represents the given distribution of weights to be implemented by the oscillatory AIMC. Generally, in neural networks, the weights tend to aggregate around a value of zero, as indicated by the distribution curve 1104. Each weight is implemented as a differential of the charge which translates into a differential of the specified conductances. For example, consider the weight corresponding to location 1108 on the distribution curve 1104. Once the Q+ 1112 that corresponds to the desired weight is identified, the corresponding conductance G+ 1116 may be identified via the graph of FIG. 11. In the case of a positive weight, for the Q− and G− parameters, Q− and G− are set to the maximum value (Q− is set to approximately zero); that is, the positive weights are essentially stored on the Q+. In the case of a negative weight, the process is inverted; that is, for the Q+ and G+ parameters, Q+ and G+ are set to the maximum value (Q+ is set to approximately zero). This technique addresses non-linearities in the oscillatory AIMC.

Refer now to FIG. 13.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

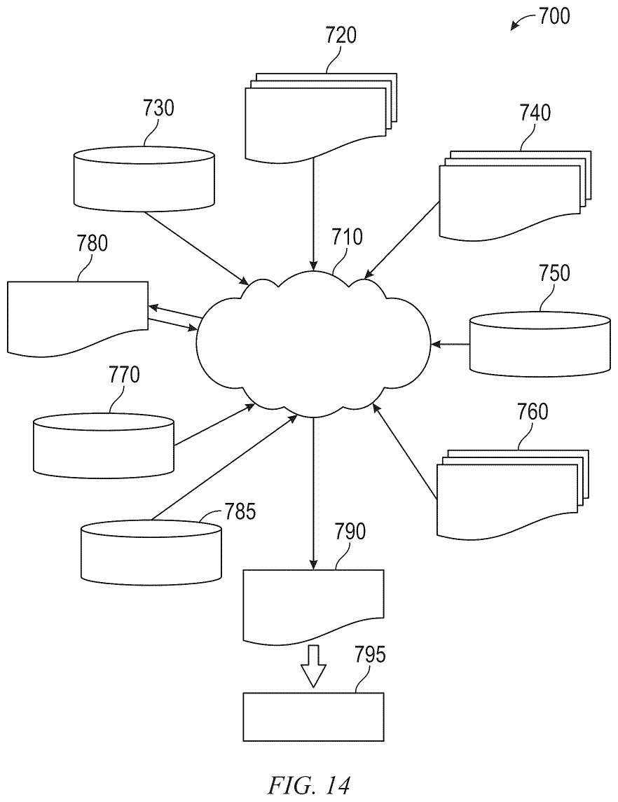

Computing environment 100 contains an example of an environment for the execution of at least some of the computer code involved in performing the inventive methods, such as oscillatory MVM control system 200 or design software for implementing aspects of the circuitry disclosed herein (e.g., via process in FIG. 14). Note also that aspects of the invention could be embodied as a co-processor within the processor set 110 In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 13. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

### Exemplary Design Process Used in Semiconductor Design, Manufacture, and/or Test

One or more embodiments make use of computer-aided semiconductor integrated circuit design simulation, test, layout, and/or manufacture. In this regard, FIG. 14 shows a block diagram of an exemplary design flow 700 used for example, in semiconductor IC logic design, simulation, test, layout, and manufacture. Design flow 700 includes processes, machines and/or mechanisms for processing design structures or devices to generate logically or otherwise functionally equivalent representations of design structures and/or devices, such as those that can be analyzed using techniques disclosed herein or the like. The design structures processed and/or generated by design flow 700 may be encoded on machine-readable storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines may include: lithography machines, machines and/or equipment for generating masks (e.g. e-beam writers), computers or equipment for simulating design structures, any apparatus used in the manufacturing or test process, or any machines for programming functionally equivalent representations of the design structures into any medium (e.g. a machine for programming a programmable gate array).

Design flow 700 may vary depending on the type of representation being designed. For example, a design flow 700 for building an application specific IC (ASIC) may differ from a design flow 700 for designing a standard component or from a design flow 700 for instantiating the design into a programmable array, for example a programmable gate array (PGA) or a field programmable gate array (FPGA) offered by Altera® Inc. or Xilinx® Inc.

FIG. 13 illustrates multiple such design structures including an input design structure 720 that is preferably processed by a design process 710. Design structure 720 may be a logical simulation design structure generated and processed by design process 710 to produce a logically equivalent functional representation of a hardware device. Design structure 720 may also or alternatively comprise data and/or program instructions that when processed by design process 710, generate a functional representation of the physical structure of a hardware device. Whether representing functional and/or structural design features, design structure 720 may be generated using electronic computer-aided design (ECAD) such as implemented by a core developer/designer. When encoded on a gate array or storage medium or the like, design structure 720 may be accessed and processed by one or more hardware and/or software modules within design process 710 to simulate or otherwise functionally represent an electronic component, circuit, electronic or logic module, apparatus, device, or system. As such, design structure 720 may comprise files or other data structures including human and/or machine-readable source code, compiled structures, and computer executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages such as Verilog and VHDL, and/or higher level design languages such as C or C++.

Design process 710 preferably employs and incorporates hardware and/or software modules for synthesizing, translating, or otherwise processing a design/simulation functional equivalent of components, circuits, devices, or logic structures to generate a Netlist 780 which may contain design structures such as design structure 720. Netlist 780 may comprise, for example, compiled or otherwise processed data structures representing a list of wires, discrete components, logic gates, control circuits, I/O devices, models, etc. that describes the connections to other elements and circuits in an integrated circuit design. Netlist 780 may be synthesized using an iterative process in which netlist 780 is resynthesized one or more times depending on design specifications and parameters for the device. As with other design structure types described herein, netlist 780 may be recorded on a machine-readable data storage medium or programmed into a programmable gate array. The medium may be a nonvolatile storage medium such as a magnetic or optical disk drive, a programmable gate array, a compact flash, or other flash memory. Additionally, or in the alternative, the medium may be a system or cache memory, buffer space, or other suitable memory.

Design process 710 may include hardware and software modules for processing a variety of input data structure types including Netlist 780. Such data structure types may reside, for example, within library elements 730 and include a set of commonly used elements, circuits, and devices, including models, layouts, and symbolic representations, for a given manufacturing technology (e.g., different technology nodes, 32 nm, 45 nm, 90 nm, etc.). The data structure types may further include design specifications 740, characterization data 750, verification data 760, design rules 770, and test data files 785 which may include input test patterns, output test results, and other testing information. Design process 710 may further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 710 without deviating from the scope and spirit of the invention. Design process 710 may also include modules for performing standard circuit design processes such as timing analysis, verification, design rule checking, place and route operations, etc.

Design process 710 employs and incorporates logic and physical design tools such as HDL compilers and simulation model build tools to process design structure 720 together with some or all of the depicted supporting data structures along with any additional mechanical design or data (if applicable), to generate a second design structure 790. Design structure 790 resides on a storage medium or programmable gate array in a data format used for the exchange of data of mechanical devices and structures (e.g. information stored in an IGES, DXF, Parasolid XT, JT, DRG, or any other suitable format for storing or rendering such mechanical design structures). Similar to design structure 720, design structure 790 preferably comprises one or more files, data structures, or other computer-encoded data or instructions that reside on data storage media and that when processed by an ECAD system generate a logically or otherwise functionally equivalent form of one or more IC designs or the like. In one embodiment, design structure 790 may comprise a compiled, executable HDL simulation model that functionally simulates the devices to be analyzed.

Design structure 790 may also employ a data format used for the exchange of layout data of integrated circuits and/or symbolic data format (e.g. information stored in a GDSII (GDS2), GL1, OASIS, map files, or any other suitable format for storing such design data structures). Design structure 790 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described herein (e.g., .lib files). Design structure 790 may then proceed to a stage 795 where, for example, design structure 790: proceeds to tape-out, is released to manufacturing, is released to a mask house, is sent to another design house, is sent back to the customer, etc.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. An oscillatory matrix-vector multiplication device comprising:
one or more oscillatory matrix-vector multiplication circuits, each oscillatory matrix-vector multiplication circuit comprising:
a first tunable resistive circuit comprising a first complementary metal-oxide semiconductor (CMOS) transistor, a first activation input, and a first tunable resistive circuit output, wherein the first complementary metal-oxide semiconductor (CMOS) transistor comprises a first gate input, a first input coupled to the first activation input and a first output coupled to the first tunable resistive circuit output, and wherein the first activation input is configured to receive an activation signal; and
a programmable oscillator circuit coupled to the first gate input of the first tunable resistive circuit and configured to produce a control signal based on a given conductance.

2. The oscillatory matrix-vector multiplication device of claim 1, wherein the first tunable resistive circuit comprises a parallel complementary metal-oxide semiconductor (CMOS) transistor coupled in parallel with the first complementary metal-oxide semiconductor transistor.

3. The oscillatory matrix-vector multiplication device of claim 1, wherein the first tunable resistive circuit comprises a serial complementary metal-oxide semiconductor (CMOS) transistor, wherein the serial complementary metal-oxide semiconductor (CMOS) transistor comprises a serial gate input, a serial input and a serial output coupled to the first output, and a capacitor, a first terminal of the capacitor coupled to the first output of the first complementary metal-oxide semiconductor (CMOS) transistor and to the serial input of the second complementary metal-oxide semiconductor (CMOS) transistor.

4. The oscillatory matrix-vector multiplication device of claim 1, wherein the programmable oscillator circuit comprises a resistor-capacitor circuit, wherein a resistor of the resistor-capacitor circuit is implemented with an analog memory device.

5. The oscillatory matrix-vector multiplication device of claim 1, wherein the programmable oscillator circuit comprises a relaxation oscillator, wherein a resistance of the relaxation oscillator is implemented with an analog memory device and determines the duty cycle.

6. The oscillatory matrix-vector multiplication device of claim 1, wherein the programmable oscillator circuit comprises a phase change memory (PCM) device.

7. The oscillatory matrix-vector multiplication device of claim 1, wherein the activation signal is pulse-code modulated.

8. The oscillatory matrix-vector multiplication device of claim 1, wherein the control signal is based on a specified duty cycle.

9. The oscillatory matrix-vector multiplication device of claim 1, wherein the control signal is based on a variable resistance-capacitance delay.

10. The oscillatory matrix-vector multiplication device of claim 1, wherein each oscillatory matrix-vector multiplication circuit further comprises:
a second tunable resistive circuit comprising a second complementary metal-oxide semiconductor (CMOS) transistor, a second activation input, and a second tunable resistive circuit output, wherein the second complementary metal-oxide semiconductor (CMOS) transistor comprises a second gate input, a second input coupled to the second activation input and a second output coupled to the second tunable resistive circuit output, wherein the second activation input is configured to receive the activation signal and wherein the programmable oscillator circuit is coupled to the second gate input of the second tunable resistive circuit.

11. The oscillatory matrix-vector multiplication device of claim 10, wherein the first tunable resistive circuit comprises a parallel complementary metal-oxide semiconductor (CMOS) transistor coupled in parallel with the first complementary metal-oxide semiconductor transistor and wherein the second tunable resistive circuit comprises a parallel complementary metal-oxide semiconductor (CMOS) transistor coupled in parallel with the second complementary metal-oxide semiconductor transistor.

12. The oscillatory matrix-vector multiplication device of claim 10, wherein the first tunable resistive circuit comprises a first serial complementary metal-oxide semiconductor (CMOS) transistor and a first capacitor;
wherein the second tunable resistive circuit comprises a second serial complementary metal-oxide semiconductor (CMOS) transistor and a second capacitor;
wherein the first serial complementary metal-oxide semiconductor (CMOS) transistor comprises a first serial gate input, a first serial input and a first serial output coupled to the first tunable resistive circuit output;
wherein the second serial complementary metal-oxide semiconductor (CMOS) transistor comprises a second serial gate input, a second serial input and a second serial output coupled to the second tunable resistive circuit output;
wherein a first terminal of the first capacitor is coupled to the first output of the first transistor complementary metal-oxide semiconductor (CMOS) transistor and to the first serial input of the second complementary metal-oxide semiconductor (CMOS) transistor; and
wherein a first terminal of the second capacitor is coupled to the second output of the second transistor complementary metal-oxide semiconductor (CMOS) transistor and to the second serial input of the second complementary metal-oxide semiconductor (CMOS) transistor.

13. The oscillatory matrix-vector multiplication device of claim 10, wherein the programmable oscillator circuit comprises a resistor-capacitor circuit, wherein a resistor of the resistor-capacitor circuit is implemented with an analog memory device.

14. The oscillatory matrix-vector multiplication device of claim 10, wherein the programmable oscillator circuit comprises a relaxation oscillator, wherein a resistance of the relaxation oscillator is implemented with an analog memory device and determines the duty cycle.

15. The oscillatory matrix-vector multiplication device of claim 10, wherein the programmable oscillator circuit comprises a phase change memory (PCM) device.

16. The oscillatory matrix-vector multiplication device of claim 1, wherein the activation signal is pulse-code modulated.

17. The oscillatory matrix-vector multiplication device of claim 1, wherein the control signal is based on a specified duty cycle.

18. The oscillatory matrix-vector multiplication device of claim 1, wherein the control signal is based on a variable resistance-capacitance delay.

19. A method for controlling an oscillatory matrix-vector multiplication device, the method comprising:
mapping a given weight to a duty cycle of a programmable oscillator circuit;
configuring the programmable oscillator circuit to produce an oscillating signal with the mapped duty cycle; and
applying the oscillating signal to a tunable resistive circuit.

20. The method of claim 19, wherein the mapping of the given weight to the duty cycle further comprises mapping the given weight to a conductance and mapping the conductance to the duty cycle.

21. An oscillatory matrix-vector multiplication device comprising:
an array of a plurality of oscillatory matrix-vector multiplication circuits, the array 448 configured as a plurality of columns and a plurality of rows of the oscillatory matrix-vector multiplication circuits, each oscillatory matrix-vector multiplication circuit comprising:
a first tunable resistive circuit comprising a first complementary metal-oxide semiconductor (CMOS) transistor, a first activation input, and a first tunable resistive circuit output, wherein the first complementary metal-oxide semiconductor (CMOS) transistor comprises a first gate input, a first input coupled to the first activation input and a first output coupled to the first tunable resistive circuit output;
a second tunable resistive circuit comprising a second complementary metal-oxide semiconductor (CMOS) transistor, a second activation input, and a second tunable resistive circuit output, wherein the second complementary metal-oxide semiconductor (CMOS) transistor comprises a second gate input, a second input coupled to the second activation input and a second output coupled to the second tunable resistive circuit output;
a programmable oscillator circuit coupled to the first gate input of the first tunable resistive circuit and coupled to the second gate input of the second tunable resistive circuit and wherein the programmable oscillator circuit is configured to produce a control signal based on a given conductance; and
a plurality of summation circuits, wherein the first input of each first tunable resistive circuit in a given row of the array and the second input of each second tunable resistive circuit in the given row of the array are coupled to an activation signal corresponding to the row, wherein the first tunable resistive circuit output of each first tunable resistive circuit in a given column of the array are coupled together and the second tunable resistive circuit output of each second tunable resistive circuit in the given column of the array are coupled together and wherein one of the plurality of summation circuits is configured to subtract a current on the coupled second tunable resistive circuit outputs of the second tunable resistive circuits in the given column of the array from the coupled first tunable resistive circuit outputs of the first tunable resistive circuits in the given column of the array.

22. The oscillatory matrix-vector multiplication device of claim 21, wherein the first tunable resistive circuit comprises a parallel complementary metal-oxide semiconductor (CMOS) transistor coupled in parallel with the first complementary metal-oxide semiconductor transistor and wherein the second tunable resistive circuit comprises a parallel complementary metal-oxide semiconductor (CMOS) transistor coupled in parallel with the second complementary metal-oxide semiconductor transistor.

23. The oscillatory matrix-vector multiplication device of claim 21, wherein the programmable oscillator circuit comprises a resistor-capacitor circuit, wherein a resistor of the resistor-capacitor circuit is implemented with an analog memory device.

24. The oscillatory matrix-vector multiplication device of claim 23, further comprising:
input peripheral circuitry for generating the activation signals based on input data, the input peripheral circuitry coupled to the first tunable resistive circuit and the second tunable resistive circuit;
output peripheral circuitry for generating an inferencing result based on outputs of the plurality of summation circuits, the output peripheral circuitry coupled to the first tunable resistive circuit and the second tunable resistive circuit; and
a controller for coordinating an inferencing operation using the oscillatory matrix-vector multiplication device.

25. A hardware description language (HDL) design structure encoded on a machine-readable data storage medium, the HDL design structure comprising elements that when processed in a computer-aided design system generates a machine-executable representation of a semiconductor structure, wherein the HDL design structure comprises:
one or more oscillatory matrix-vector multiplication circuits, each oscillatory matrix-vector multiplication circuit comprising:
a first tunable resistive circuit comprising a first complementary metal-oxide semiconductor (CMOS) transistor, a first activation input, and a first tunable resistive circuit output, wherein the first complementary metal-oxide semiconductor (CMOS) transistor comprises a first gate input, a first input coupled to the first activation input and a first output coupled to the first tunable resistive circuit output, and wherein the first activation input is configured to receive an activation signal; and
a programmable oscillator circuit coupled to the first gate input of the first tunable resistive circuit and configured to produce a control signal based on a given conductance.
